(19) United States
(12) Patent Application Publication
(10) Pub. No.: US 2025/0194285 A1
(43) Pub. Date: Jun. 12, 2025

(54) Photocoupler

(71) Applicant: Matsusada Precision, Inc., Shiga (JP)

(72) Inventors: Sadayoshi MATSUDA, Shiga (JP); Toshiaki TERAMOTO, Shiga (JP)

(21) Appl. No.: 18/531,831

(22) Filed: Dec. 7, 2023

(51) Int. Cl. H01L 31/173; H01L 31/0203; H01L 31/0232

(52) U.S. Cl. CPC H10F 55/255; H10F 77/407; H10F 77/50

(57) ABSTRACT

A photocoupler includes a light emitting part, a light receiving part, and a housing. The light emitting part is a discrete part includes a light emitting element, an input side terminal, and a first covering part covers the light emitting element. The light receiving part is a discrete part includes a light receiving element, an output side terminal, and a second covering part covers the light receiving element. The housing constitutes an internal space accommodates the light emitting element and the light receiving element. The housing includes an input side through hole and an output side through hole provided at different positions. The input side terminal is inserted into the input side through hole and protrudes from the internal space to outside of the housing. The output side terminal is inserted into the output side through hole and protrudes from the internal space to outside of the housing.

### BACKGROUND OF THE INVENTION

### Technological Field

The present invention relates to a photocoupler. More specifically, the present invention relates to a high voltage photocoupler.

### Description of the Related Art

Photocouplers are known as elements for transmitting a signal from the input side to the output side while electrically insulating the input side and the output side. Conventional photocouplers are disclosed in documents. They disclose a photocoupler having a structure in which a light emitting element and a light receiving element are each sealed with resin.

A photocoupler according to one technique includes a light emitting chip placed on a substrate and having a light emitting element, a light receiving chip placed on the substrate and having a light receiving element, translucent first resin sealing the light emitting chip and the light receiving chip, light-shielding second resin surrounding the first resin, and reflective third resin covering a top surface of the first resin.

A photocoupler according to another technique is equipped with a light emitting element mounted on an input side lead frame and a light receiving element mounted on an output side lead frame. The light emitting element and the light receiving element are opposite to each other. Each of the light emitting element and the light receiving element is sealed with translucent resin. The input side lead frame and a surface of the light emitting element are electrically connected by a bonding wire. The output side lead frame and a surface of the light receiving element are electrically connected by a bonding wire. The light receiving chip is connected to the lead on the substrate by a bonding wire. The light emitting chip is connected to the lead on the substrate by a bonding wire.

### SUMMARY OF THE INVENTION

According to the techniques, the light emitting elements and the light receiving elements are both of a surface mounting type. The bonding wire electrically connects the surface of the light emitting element and the lead frame and the bonding wire electrically connects the surface of the light receiving element and the lead frame are adjacent to each other at a close distance with only the resin separating them. For this reason, when a high voltage is applied between the input side and the output side, a short circuit easily occurred between the bonding wire of the light emitting element and the bonding wire of the light receiving element, so that the withstand voltage of the photocoupler was low. For this reason, a transformer was used instead of a photocoupler for equipment requiring a high voltage resistance between the input and output sides. Since a transformer is larger and has a more complex configuration than a photocoupler, the adoption of a transformer led to an increase in the size of the entire device configuration.

The distance between the bonding wire of the light emitting element and the bonding wire of the light receiving element depends on how to connect the bonding wire of the light emitting element and the bonding wire of the light receiving element (In other words, the shape of the bonding wire). For this reason, according to the techniques, the withstand voltage of the photocoupler changed depending on how the bonding wires were connected, making it difficult to design the withstand voltage accurately.

The present invention is to solve the above problems, the object is to provide a high voltage photocoupler. Another object of the present invention is to provide a photocoupler whose the withstand voltage can be designed accurately.

According to one aspect of this invention, a photocoupler with a light emitting part, a light receiving part, and a housing wherein the light emitting part is a discrete part including a light emitting element that emits light, an input side terminal electrically connected to the light emitting element, and a first covering part that covers the light emitting element, the light receiving part is a discrete part including a light receiving element that receives light from the light emitting element, an output side terminal electrically connected to the light receiving element, and a second covering part that covers the light receiving element, the housing constitutes an internal space that accommodates the light emitting element and the light receiving element, the housing includes an input side through hole and an output side through hole provided at different positions, the input side terminal is inserted into the input side through hole and protrudes from the internal space to outside of the housing, and the output side terminal is inserted into the output side through hole and protrudes from the internal space to outside of the housing.

In some examples, the light emitting element and the light receiving element face each other in one direction, and the housing includes a bottom part that covers lower parts of the light emitting element and the light receiving element, a ceiling part that covers upper parts of the light emitting element and the light receiving element, and first and second side surface parts facing each other in the one direction.

In some examples, the housing further includes a mark indicating a direction from the input side terminal to the output side terminal.

In some examples, the housing further includes a protrusion protruding downward from the bottom part.

In some examples, the housing further includes a first guide part provided between the light emitting element and the first side surface part, and a second guide part provided between the light receiving element and the second side surface part, wherein the input side through hole is provided in at least one of the bottom part and the first guide part, and the output side through hole is provided in at least one of the bottom part and the second guide part.

In some examples, the housing is black.

In some examples, the input side terminal is removable from the input side through hole, and the output side terminal is removable from the output side through hole.

In some examples, the photocoupler further comprising an optical fiber, wherein light from the light emitting element travels inside the optical fiber and enters the light receiving element.

In some examples, the light emitting part further includes a mounting part that constitutes a space that accommodates the light emitting element together with the first covering part, there are the two input side terminals, each of the two input side terminals passing through the mounting part, the second covering part seals the light receiving element, and there are the two output side terminals, and each of the two output side terminals protrudes from the second covering part.

According to the present invention, it is possible to provide a photocoupler with a high withstand voltage. In addition, it is possible to provide a photocoupler whose the withstand voltage can be designed accurately.

### BRIEF DESCRIPTION OF THE DRAWINGS

FIG. 1 is a perspective view showing the configuration of photocoupler 1 in one embodiment of the present invention.

FIG. 2 is a diagram showing the internal configuration of housing 4 of photocoupler 1 according to the embodiment of the present invention.

FIG. 3 is a front view showing the configuration of photocoupler 1 mounted on circuit board SB in one embodiment of the present invention.

FIG. 4 is a plan view showing the configuration of bottom part 41 of housing 4.

FIG. 5 is a diagram showing an example of the configuration of light emitting part 2.

FIG. 6 is a diagram showing an example of the configuration of light receiving part 3.

FIG. 7 is a diagram showing the internal configuration of housing 4 of photocoupler 1 in a modification of the embodiment of the present invention.

### DETAILED DESCRIPTION OF EMBODIMENTS

Hereinafter, an embodiment of the present invention will be described with reference to the drawings. Note that the x-axis, the y-axis, and the z-axis in the drawings are orthogonal to each other. In the following explanation, it is sometimes written that the positive direction of the x-axis is left, the negative direction of the x-axis is right, the positive direction of the y-axis is forward, the negative direction of the y-axis is backward, the positive direction of the z-axis is up, and the negative direction of the z-axis is down.

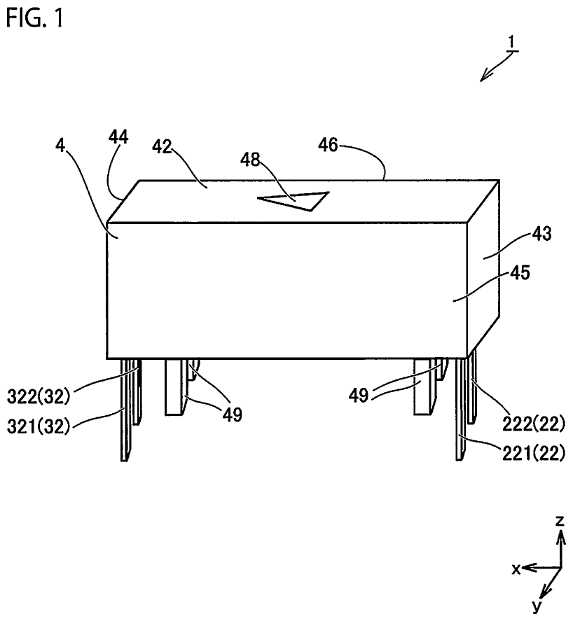

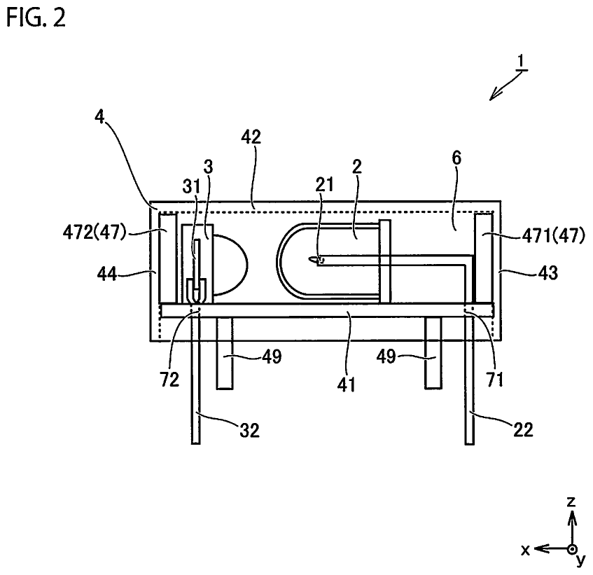

FIG. 1 is a perspective view showing the configuration of photocoupler 1 in one embodiment of the present invention. FIG. 2 is a diagram showing the internal configuration of housing 4 of photocoupler 1 according to the embodiment of the present invention. In FIG. 2, housing 4 is shown as being transparent. The boundaries between each of the ceiling part 42, the right side surface part 43, and the left side surface part 44 of the housing 4 and the internal space 6 of the housing 4 are indicated by dotted lines. In FIG. 2, the positions of the light emitting element 21, the input side through hole 71, and the output side through hole 72 are indicated by dotted lines.

Referring to FIGS. 1 and 2, a photocoupler 1 according to the present embodiment has a light emitting part 2 forming an input side and a light receiving part 3 forming an output side electrically insulated from each other, and transmits signals from the input side to the output side. Photocoupler 1 includes light emitting part 2, light receiving part 3, housing 4, etc. Each of light emitting part 2 and light receiving part 3 is a discrete part (a discrete component), for example an electronic part with lead wires. A discrete part is an electric component with a single function, having terminals for connecting it to an electric circuit. An electronic part with lead wires is an electric component that can be attached to a substrate by inserting the terminal into a through hole of the substrate. Light emitting part 2 and light receiving part 3 are insulated from each other. The light emitting part 2 and the light receiving part 3 may have different external dimensions. A “discrete” component (“discrete” part) is an elementary electronic device constructed as a single unit. A “discrete” component can be defined as a single part of an electrical circuit with one dominant function.

Light emitting part 2 is, for example, an LED (Light Emitting Diode), and includes light emitting element 21, input side terminal 22, and so on. Light emitting element 21 consists of a semiconductor element which includes a p-n junction. Light emitting element 21 emits light according to signals (current) input from input side terminal 22. Input side terminal 22 protrudes from internal space 6 to the outside of housing 4. Input side terminal 22 is electrically connected to light emitting element 21 and includes two lead terminals 221 and 222. The number of input side terminals 22 is arbitrary.

Light receiving part 3 is, for example, a PD (Photodiode) and includes light receiving element 31, output side terminal 32, etc. Light receiving element 31 consists of a semiconductor element which includes a p-n junction. Light receiving element 31 receives the light (light mainly generated from light emitting element 21 and traveling to the left) from light emitting element 21 and outputs signals (current) according to the amount of received light to output side terminal 32. Light emitting element 21 and light receiving element 31 are each accommodated in internal space 6 constituted by housing 4, and are opposed to each other in the left and right direction. Output side terminal 32 protrudes from internal space 6 to the outside of housing 4. Output side terminal 32 is electrically connected to light receiving element 31 and contains two lead terminals 321 and 322. The number of output side terminals 32 is arbitrary.

The housing 4 has any shape. Here, housing 4 has a substantially rectangular parallelepiped shape, and includes bottom part 41, ceiling part 42, right side surface part 43, left side surface part 44, front side surface part 45, back side surface part 46, and two guide parts 47 and so on. Bottom part 41 is equipped with light emitting element 21 and light receiving element 31. Bottom part 41 covers the bottom of each of light emitting element 21 and light receiving element 31. Input side terminal 22 and output side terminal 32 each pass through bottom part 41 and extend downward from bottom part 41.

Ceiling part 42 covers the top of each of light emitting element 21 and light receiving element 31. Ceiling part 42 faces bottom part 41 in the vertical direction.

Right side surface part 43, left side surface part 44, front side surface part 45, and back side surface part 46 each extend downward from ceiling part 42 and are at least provided between bottom part 41 and ceiling part 42. Right side surface part 43 covers the right side of each of light emitting element 21 and light receiving element 31. Left side surface part 44 covers the left side of each of light emitting element 21 and light receiving element 31. Right side surface part 43 and left side surface part 44 face each other in the left and right direction. The inner wall surface of right side surface part 43 is adjacent to guide part 471 (an example of a first guide part) which is the right side of the two guide parts 47. The inner wall surface of left side surface part 44 is adjacent to guide part 472 (an example of a second guide part) which is the left side of the two guide parts 47.

Front side surface part 45 covers the front side of each of light emitting element 21 and light receiving element 31. Back side surface part 46 covers the rear side of each of light emitting element 21 and light receiving 155 element 31. Front side surface part 45 and back side surface part 46 face each other in the front-rear direction. The inner wall surface of front side surface part 45 is adjacent to each of light emitting part 2, light receiving part 3, and two guide parts 47. The inner wall surface of back side surface part 46 is adjacent to each of light emitting part 2, light receiving part 3, and two guide parts 47.

Each of the two guide parts 47 is provided in internal space 6 and protrudes upward from bottom part 41. The right guide part 471 of the two guide parts 47 is provided between the light emitting element 21 and the right side surface part 43. Guide part 472 on the left of the two guide parts 47 is provided between light receiving element 31 and left side surface part 44.

The combination of bottom part 41 and two guide parts 47 is sometimes referred to as a base part. The portions of housing 4 excluding the base part (that is, ceiling part 42, right side surface part 43, left side surface part 44, front side surface part 45, and back side surface part 46) is removable from the base part. When installing the parts of housing 4 excluding the base part on bottom part 41, each of the two guide parts 47 contacts the inner wall surface of each of the right side surface part 43 and left side surface part 44, and serves to guide each of the right side surface part 43 and left side surface part 44.

Housing 4 is preferably black. Hence, light to be entered to internal space 6 from outside housing 4 can 170 be blocked, and the gain of photocoupler 1 can be improved. The housing 4 may be of a color other than black if the loss of transmitted light to the outside is negligible.

It is preferable that the lower ends of each of right side surface part 43, left side surface part 44, front side surface part 45, and back side surface part 46 extend below bottom part 41. Hence, light to be entered to internal space 6 from below outside housing 4 can be blocked.

Housing 4 further includes mark 48 and protrusions 49. Mark 48 indicates the direction from input side terminal 22 to output side terminal 32. The mark 48 is preferably a mark indicating a direction, and is made of a shape such as a triangle or an arrow. The mark 48 may contain characters. The mark 48 is preferably provided on the outer wall surface of housing 4, for example, on the outer wall surface of ceiling part 42 or on the outer wall surface of bottom part 41. It is difficult to distinguish input side terminal 22 and output side terminal 32 from each other only by the externally exposed portion from housing 4. By providing mark 48, the user of photocoupler 1 can easily distinguish between input side terminal 22 and output side terminal 32.

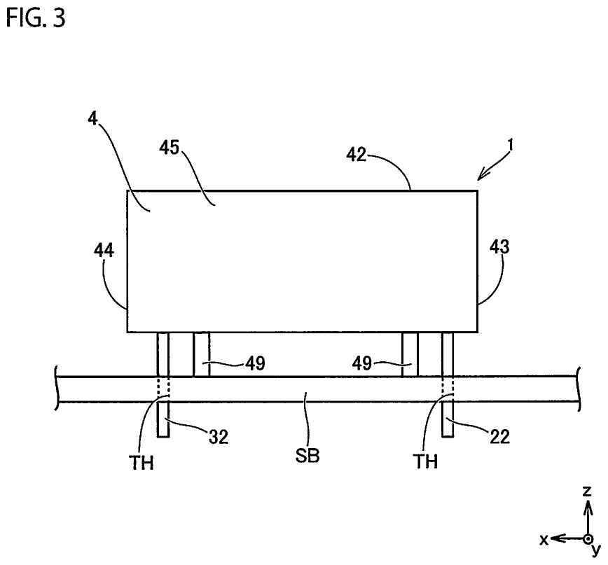

The protrusions 49 protrude downward from bottom part 41. The protrusions 49 may be plural, and here is four. When there are a plurality of protrusions 49, the plurality of protrusions 49 may be provided equally in each of the left-right direction and the front-back direction. It is preferable that the plurality of protrusions 49 have the same amount of protrusion from bottom part 41. By doing so, photocoupler 1 can be stably fixed to the circuit board. As described in FIG. 3, protrusions 49 may be located between input side terminal 22 and output side terminal 32. Protrusions 49 may be provided outside the input side terminal 22 and output side terminal. Protrusions 49 may be provided both outside the input side terminal 22 and output side terminal and inside the input side terminal 22 and output side terminal.

FIG. 3 is a front view showing the configuration of photocoupler 1 mounted on circuit board SB in one embodiment of the present invention. In FIG. 3, the position of each of the plurality of through holes TH is indicated by a dotted line.

Referring to FIGS. 2 and 3, a plurality of through holes TH are provided at different positions on the circuit board SB, when viewed from the top. When installing photocoupler 1 on circuit board SB, each of input side terminal 22 and output side terminal 32 is inserted into each of multiple through holes TH, so that the lower end of each of multiple protrusions 49 contacts circuit board SB. Then, each of input side terminal 22 and output side terminal 32 is fixed inside each of the plurality of through holes TH with solder. By providing protrusions 49, if there is foreign matter such as dust on the top surface of circuit board SB, it is possible to prevent discharge caused by the foreign matter.

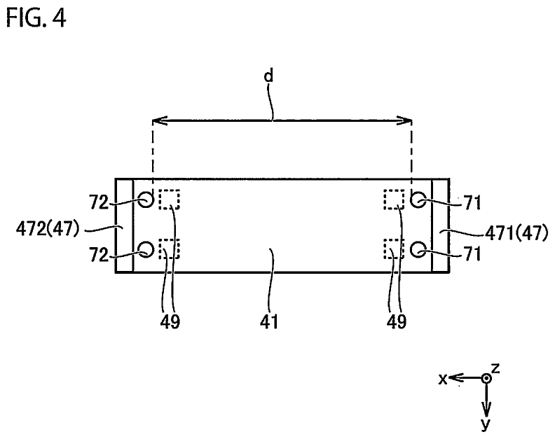

FIG. 4 is a plan view showing the configuration of bottom part 41 of housing 4. Note that in FIG. 4, the positions of each of the plurality of protrusions 49 are indicated by dotted lines.

Referring to FIGS. 2 and 4, housing 4 further includes input side through holes 71 and output side through holes 72 provided at different positions. The withstand voltage of photocoupler 1 is defined by the creepage distance or the space distance d between input side through holes 71 and output side through holes 72. Input side through holes 71 are holes into which input side terminals 22 is inserted, and the number of the holes being provided corresponds to the number of input side terminals 22 (two in this embodiment). When there are a plurality of input side through holes 71, the plurality of input side through holes 71 may be provided along the front-rear direction. Input side through holes 71 may be provided on at least one of bottom part 41 and guide part 471 on the right side. Output side through holes 72 are holes into which output side terminals 32 are inserted, and the number of the holes being provided corresponds to the number of output side terminals 32 (two in this embodiment). When there are a plurality of output side through holes 72, the plurality of output side through holes 72 may be provided along the front-rear direction. Output side through holes 72 may be provided on at least one of bottom part 41 and guide part 472 on the left side.

Protrusions 49 may be provided between input side through holes 71 and output side through holes 72 as 215 shown in FIG. 4. Here, there are four protrusions 49, and each of the four protrusions 49 is provided at a position corresponding to each of two input side through holes 71 and a position corresponding to each of two output side through holes 72. By providing protrusions 49 at such the positions, the creepage distance between input side terminal 22 and output side terminal 32 can be increased.

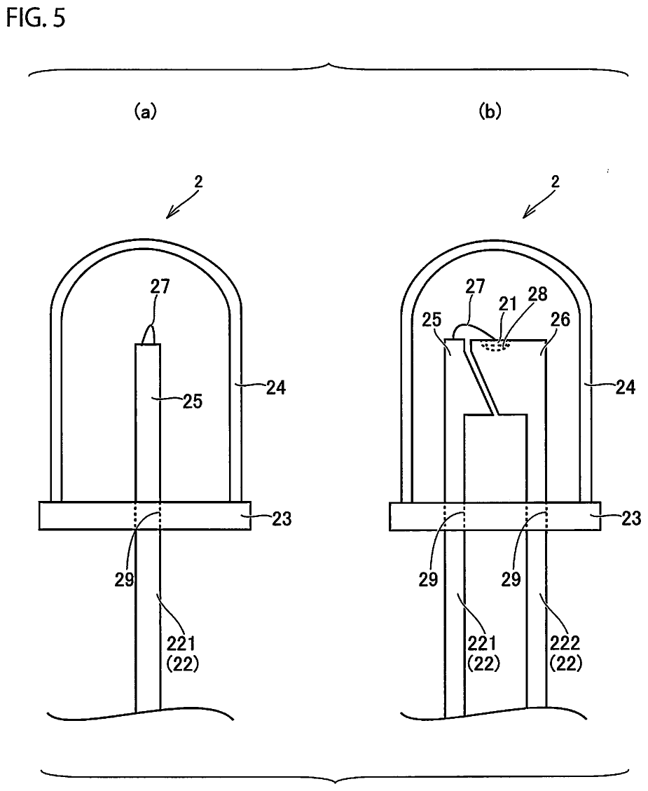

FIG. 5 is a diagram showing an example of the configuration of light emitting part 2. FIG. 5 (a) is a front 220 view, and FIG. 5 (b) is a side view. In FIG. 5, the positions of light emitting element 21, reflective surface 28, and fixing hole 29 are indicated by dotted lines.

Referring to FIG. 5, the light emitting part 2 further includes a mounting part 23, a lens part 24, an anode frame 25, a cathode frame 26, a wire 27, a reflective surface 28, and two fixing holes 29. Light emitting part 2 is also called a bullet-shaped LED, a round-shaped LED, or a lead frame shaped LED.

The mounting part 23 is made of an insulator such as resin, and is equipped with a light emitting element 21. Lens part 24 covers light emitting element 21. The mounting part 23 and the lens part 24 constitute an internal space of the light emitting part 2, and the light emitting element 21 and so on are accommodated in this internal space. The lens part 24 is preferably made of an optically transparent material such as resin. The lens part 24 has a circular shape when viewed from above, and its diameter is, for example, 3 millimeters to 10 millimeters.

Two fixing holes 29 are each formed in the mounting part 23. Each of the two input side terminals 22 is inserted into each of the two fixing holes 29 and fixed in each of the two fixing holes 29. Each of the two input side terminals 22 extends downward through the mounting part 23.

Each of the anode frame 25 and cathode frame 26 is made of conductor. The upper end of the lead terminal 221 of the input side terminal 22 is electrically connected to the anode frame 25. The upper end of the lead terminal 222 of the input side terminal 22 is electrically connected to the cathode frame 26.

A recessed part is formed on the top surface of the cathode frame 26, and the light emitting element 21 is provided inside the recessed part. The wire 27 electrically connects the p-type semiconductor of the light emitting element 21 and the anode frame 25. The n-type semiconductor of the light emitting element 21 is electrically connected to the cathode frame 26. The reflective surface 28 is provided on the surface of the recessed part and plays the role of reflecting the light of the light emitting element 21.

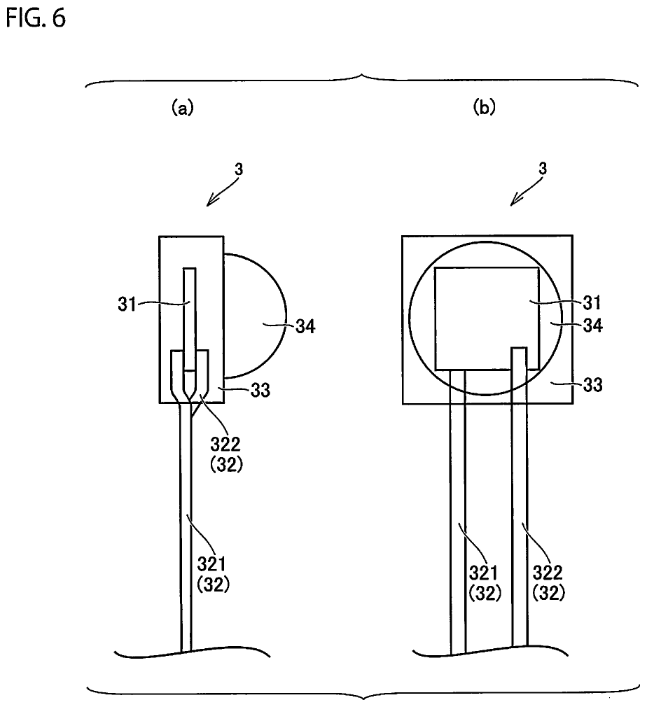

FIG. 6 is a diagram showing an example of a configuration of light receiving part 3. FIG. 6 (a) is a front view, and FIG. 6 (b) is a side view.

Referring to FIG. 6, light receiving part 3 further includes reception section 33 and lens part 34. The reception section 33 is made of a translucent insulator such as resin. The reception section 33 covers the light receiving element 31 and seals the light receiving element 31. The reception section 33 further seals the vicinity of the upper end of each of the two output side terminals 32. The upper end of the lead side terminal 321 of the output side terminal 32 is electrically connected to the p-type semiconductor of the light receiving element 31. The upper end of the lead terminal 322 of the output side terminal 32 is electrically connected to the n-type semiconductor of the light receiving element 31. Each of the two output side terminals 32 protrudes from the reception section 33. The reception section 33 has, for example, a square shape when viewed from the side, and the length of one side thereof is, for example, 5 millimeters to 15 millimeters.

Lens part 34 is fixed to the side surface of reception section 33. The lens part 34 collects light from the light emitting element 21 onto the light receiving element 31. Lens part 34 is made of optically transparent material such as resin.

### Effects of the Embodiments

According to this embodiment, light emitting element 21 is covered by the lens part 24, and the light receiving element 31 is covered by the reception section 33. The light emitting element 21 and the light receiving element 31 are separated by at least a lens part 24 and a reception section 33. Hence, short circuit between a member near the light emitting element 21 and a member near the light receiving element 31 is less likely to occur, and the withstand voltage of the photocoupler 1 depends on the creepage distance or space distance between the input side terminal 22 and the output side terminal 32. As a result, a high-voltage photocoupler can be realized. Since there is no need to use a transformer in place of the photocoupler, it is possible to downsize the overall configuration of the equipment in which the photocoupler is installed.

Since each of the input side terminal 22 and the output side terminal 32 penetrates each of the input side through hole 71 and the output side through hole 72, the withstand voltage of the photocoupler 1 is determined by the formation position of each of the input side through hole 71 and the output side through hole 72. As a result, it becomes possible to accurately design the photocoupler's withstand voltage.

In some examples, the input side terminal 22 is removable from the input side through hole 71, and the output side terminal 32 is preferably removable from the output side through hole 72. Hence, a combination of light emitting part 2 and light receiving part 3 depending on the performance required for photocoupler 1 can be adopted from among a large number of light emitting parts and light receiving parts having various characteristics. In particular, depending on the performance required for photocoupler 1 such as the response speed and the gain, it is possible to adopt a combination of light emitting part 2 and light receiving part 3 such that the emission intensity of the light emitting part, the emission wavelength of the light emitting part, or the sensitivity of the light receiving part is appropriate.

Further, by using multiple photocouplers 1, with one input side control unit, it is possible to uniformly control the driving of each of a plurality of output side circuits having mutually different potentials. In this case, a plurality of photocouplers 1 each having an appropriate withstand voltage are prepared for each of a plurality of output-side circuits having mutually different potentials. Input side terminal 22 of each of the multiple selected photocouplers 1 is connected in series to the one control unit, and output side terminal 32 of each of the multiple selected photocouplers 1 is connected to each of the multiple output side circuits.

### Modification

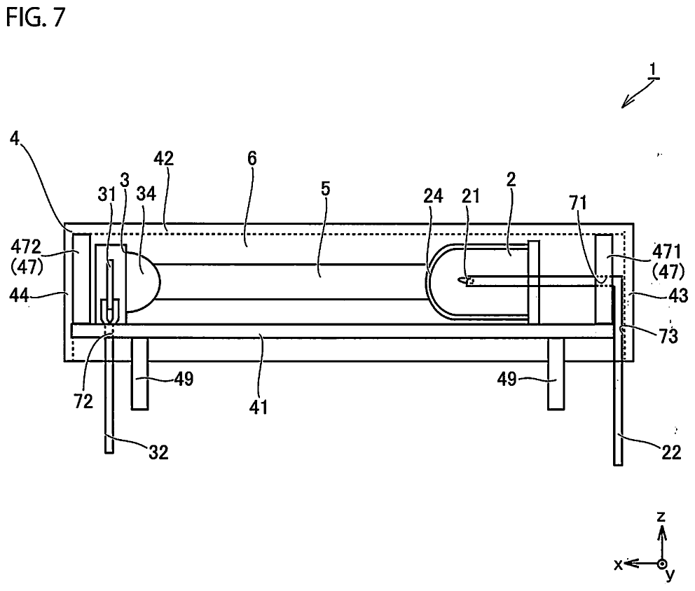

FIG. 7 is a diagram showing the internal configuration of housing 4 in photocoupler 1 of a modification of an embodiment of the present invention. In FIG. 7, housing 4 is shown as being transparent. The boundaries between each of the ceiling part 42, the right side surface part 43, and the left side surface part 44 of the housing 4 and the internal space 6 of the housing 4 are indicated by dotted lines. In FIG. 7, the positions of light emitting element 21, input side through hole 71, and output side through hole 72 are indicated by dotted lines.

Referring to FIG. 7, photocoupler 1 of this modification further includes optical fiber 5. Optical fiber 5 is provided between light emitting element 21 and light receiving element 31. The right end of optical fiber 5 is fixed to lens part 24 of light emitting part 2, for example. The left end of optical fiber 5 is fixed to lens part 34 of light receiving part 3, for example. Optical fiber 5 is made of, for example, a plastic fiber or a quartz glass fiber. A member for fixing optical fiber 5 may be provided on housing 4. Optical fiber 5 may be fixed to housing 4 or bottom part 41.

Input side through hole 71 is located at guide part 47 on the right. The terminal that passed through input 295 side through hole 71 further passes through space 73 and extends downward from bottom part 41. The space 73 is a space between the right end of bottom part 41 and the inner wall surface of right side surface part 43.

Since the configurations of this modification other than the above is the same as the configurations of the above-described embodiment shown in FIGS. 1 to 6, the same members are given the same numerals, the description will not be repeated.

According to this modification, the light from the light emitting element 21 enters the inside of the optical fiber 5 from one end of the optical fiber 5, and travels inside the optical fiber 5 while repeating total reflection inside the optical fiber 5. The light emitted from the optical fiber 5 enters the light receiving element 31. Hence, even if the distance between the light emitting element 21 and the light receiving element 31 is long, attenuation of the light of the light emitting element 21 can be suppressed. As a result, it is possible to increase the creepage distance and space distance between input side terminal 22 and output side terminal 32 while suppressing a decrease in the gain of photocoupler 1, the withstand voltage of photocoupler 1 can be improved.

In addition, since the input side through hole 71 is provided on the right guide part 47, the creepage distance and space distance between the input side through hole 71 and the output side through hole 72 can be increased. The output side through hole 72 may be provided on the left guide part 47. In this case as well, the creepage distance and space distance between the input side through hole 71 and the output side through hole 72 can 310 be increased.

### [Others]

The above-described embodiments and modifications should be considered to be illustrative in all respects and not restrictive. The scope of the present invention is indicated by the scope of claims rather than the above description and is intended to include the claims and all changes within the meaning and scope of the equivalent.

### EXPLANATION OF SYMBOLS

1 photocoupler (an example of a photocoupler)
2 light emitting part (an example of a light emitting part)
3 light receiving part (an example of a light receiving part)
4 housing (an example of a housing)
5 optical fiber (an example of an optical fiber)
6 internal space
21 light emitting element of the light emitting part (an example of a light emitting element)
22 input side terminal of the light emitting part (an example of an input side terminal)
23 mounting part of the light emitting part (an example of a mounting part)
24 lens part of the light emitting part (an example of a first covering part)
25 anode frame of the light emitting part
26 cathode frame of the light emitting part
27 wire of the light emitting part
28 reflective surface of the light emitting part
29 fixing hole of the light emitting part
31 light receiving element of the light receiving part (an example of a light receiving element)
32 output side terminal of the light receiving part (an example of an output side terminal)
33 reception section of the light receiving part (an example of a second covering part)
34 lens part of the light receiving part
41 bottom part of the housing (an example of a bottom part)
42 ceiling part of the housing (an example of a ceiling part)
43 right side surface part of the housing (an example of a first side surface part)
44 left side surface part of the housing (an example of a second side surface part)
45 front side surface part of the housing
46 back side surface part of the housing
47, 471, 472 guide part of the housing (an example of a first and a second guide parts)
48 mark of the housing (an example of a mark)
49 protrusion of the housing (an example of a protrusion)
71 input side through hole of the housing (an example of an input side through hole)
72 output side through hole of the housing (an example of an output side through hole)
73 space
221, 222, 321, 322 lead terminal
SB circuit board
TH through hole

What is claimed is:

1. A photocoupler with a light emitting part, a light receiving part, and a housing, wherein:
the light emitting part is a discrete part including a light emitting element that emits light, an input side terminal electrically connected to the light emitting element, and a first covering part that covers the light emitting element;
the light receiving part is a discrete part including a light receiving element that receives light from the light emitting element, an output side terminal electrically connected to the light receiving element, and a second covering part that covers the light receiving element;
the housing has there-within an internal space that accommodates the light emitting element and the light receiving element;
the housing includes an input side through hole and an output side through hole provided at different positions; and
the input side terminal is inserted into the input side through hole and protrudes from the internal space to outside of the housing; wherein
the output side terminal is inserted into the output side through hole and protrudes from the internal space to outside of the housing.

2. The photocoupler according to claim 1, wherein:
the light emitting element and the light receiving element face each other in one direction, and
the housing includes
a bottom part that covers lower parts of the light emitting element and the light receiving element,
a ceiling part that covers upper parts of the light emitting element and the light receiving element, and
first and second side surface parts facing each other in the one direction.

3. The photocoupler according to claim 2, wherein:
the housing further includes a mark indicating a direction from the input side terminal to the output side terminal.

4. The photocoupler according to claim 2, wherein:
the housing further includes a protrusion protruding downward from the bottom part.

5. The photocoupler according to claim 2, wherein:
the housing further includes
a first guide part provided between the light emitting element and the first side surface part, and The photocoupler according to claim 1, further comprising:
the light emitting part further includes a mounting part that constitutes a space that accommodates the light emitting element together with the first covering part,
there are the two input side terminals, each of the two input side terminals passing through the mounting the output side through hole is provided in at least one of the bottom part and the second guide part.

6. The photocoupler according to claim 1, wherein:
the housing is black.

7. The photocoupler according to claim 1, wherein:
the input side terminal is removable from the input side through hole, and
the output side terminal is removable from the output side through hole.

8. The photocoupler according to claim 1, further comprising:
an optical fiber, wherein light from the light emitting element travels inside the optical fiber and enters the light receiving element.

9. The photocoupler according to claim 1, wherein:
the light emitting part further includes a mounting part that constitutes a space that accommodates the light emitting element together with the first covering part,
there are the two input side terminals, each of the two input side terminals passing through the mounting part,
the second covering part seals the light receiving element, and
there are the two output side terminals, and each of the two output side terminals protrudes from the second covering part.
